(19) United States
(12) Patent Application Publication
(10) Pub. No.: US 2008/0008570 A1
(43) Pub. Date: Jan. 10, 2008

(54) BRIDGE LOADPORT AND METHOD

(76) Inventors: Theodore W. Rogers, Alameda, CA (US); Roumen I. Deyanov, Santa Clara, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 11/774,928

(22) Filed: Jul. 9, 2007

Related U.S. Application Data
(63) Continuation-in-part of application No. 11/599,020, filed on Nov. 13, 2006.
(60) Provisional application No. 60/819,603, filed on Jul. 10, 2006.

(51) Int. Cl. H01L 21/00

(52) U.S. Cl. 414/292; 414/323; 414/422; 414/612; 414/672; 414/935

(57) ABSTRACT

A bridge loadport is described comprising a tool interface, an advance plate assembly, a port plate, and a port door. The tool interface extends vertically and is configured to substantially cover one end of a process tool. The advance plate assembly is supported on the front side of the tool interface and is configured to support a front-opening unified pod (pod). The port plate extends vertically, covering an upper portion of the tool interface. An aperture having a size and shape that substantially matches a size and shape of a door of a pod is formed in the port plate. The port door has a port door actuator and a port door face attached to the port door actuator. In one embodiment, the port door face is movable with respect to the port door actuator along a ling perpendicular to the aperture.

### CLAIM FOR PRIORITY

This Application claims benefit of earlier-filed and co-pending U.S. Provisional Patent Application 60/819,603 filed on Jul. 10, 2006, and entitled, “Bridge load port with variable lot size capability,” which is incorporated herein by reference in its entirety.

This Application is a continuation-in-part of related U.S. patent application Ser. No. 11/599,020, filed Nov. 13, 2006, and entitled, “Load Port Door With Simplified FOUP Door Sensing and Retaining Mechanism,” which is also incorporated herein by reference in its entirety.

### BACKGROUND

During semiconductor manufacturing, semiconductor wafers and other substrates may undergo a plurality of process steps, each of which are performed by a specialized process tool. Pods are used to convey substrates from one tool to another. An exemplary type of pod is referred to as a front-opening unified pod (FOUP). Each pod is capable of transporting a number of substrates of a specific size. For example, for wafers having a diameter of 300 mm, a conventional FOUP has a capacity of 25 wafers, and can therefore carry 25 or fewer 300 mm wafers at a time. The pods are designed to maintain a protected internal environment to keep the wafers free of contamination, e.g., by particulates in the air outside the pod.

A lot size is the number of substrates being processed as a group. A pod having a maximum capacity of 25 substrates is appropriate for a lot size of 25, since each 25-substrate lot can be kept together during processing and conveyed from one tool to another in a single pod. However, some fabricators are moving to reduce their lot size for a variety of reasons. Storing a 10-substrate lot in a pod designed for 25 substrates can be space-inefficient, resulting in a greatly reduced storage density. In a fabrication facility where floor space can be precious, it may be desirable to increase the storage density by storing the substrate lots in smaller size pods, each having a smaller maximum capacity e.g., 8 or 10 substrates each. However, each pod is designed specifically to interface with a particular load port in each tool and each load port is correspondingly designed to fit a standard 25-substrate pod. Therefore, simply resizing the pod would result in an incompatibility between the pod and the load port. A redesign of the load port is possible so that the load port can then accommodate the smaller-capacity pod, however, this is an expensive proposition which may not provide compatibility with future lot size changes.

In the semiconductor industry, as wafer sizes increase, the number of devices formed into each wafer increases, improving yield per wafer. Wafer sizes have been steadily increasing since the early 1960s from 10 mm to the now common 300 mm diameter size. Many fabricators are transitioning or are planning to transition to a new 450 mm diameter standard. As with the change in lot size, accommodating this change in wafer diameter is expensive, requiring new tools, new pods, new load ports, and new conveyances. It would be desirable to provide a flexible load port capable of being easily and cheaply reconfigured to accommodate multiple size wafers.

FIGS. 1 and 2 show a conventional load port 10 configured to interface with a standard 300 mm, 25-wafer pod 70 (shown in FIG. 2). Load port 10 includes a tool interface 20. Typically, tool interface 20 is in conformance with the standard for Box Opener/Loader-to-Tool Standard Interface (BOLTS), commonly referred to as a BOLTS interface or a BOLTS plate. Tool interface 20 includes an aperture 22 surrounded by a recessed shoulder 24. Aperture 22 is occluded by a port door 30. Port door 30 forms a proximity seal with aperture 22 to prevent contaminates from migrating to the interior of process tool 40. A proximity seal takes advantage of a positive interior pressure that is maintained by process tool 40, and provides a small amount of clearance, e.g., about 1 mm, between the parts forming the proximity seal, allowing air to escape process tool 40 and sweep away any particulates from the sealing surfaces.

Load port 10 also includes an advance plate assembly 50 having an advance plate 52. Registration pins 54 mate with corresponding slots or recesses in the bottom support 72 of pod 70. Advance plate assembly 50 has an actuator (not shown) that slides advance plate 52 between the retracted position shown and an advanced position that is proximate tool interface 20.

Port door 30 is moved from the closed position shown in FIGS. 1 and 2 to an open position. In the closed position, port door 30 substantially occludes aperture 22 of tool interface 20. Port door 30 is moved from the closed position by mechanism 32 which translates port door 30 to the right (as viewed in FIG. 2) and then down to the open position. In the open position, aperture 22 and the interior of pod 70 remains substantially unobstructed by port door 30. The front surface 34 of port door 30 includes a pair of latch keys 60. Latch keys 60 include a post 62 and a crossbar 64, and are configured to rotate on the axis of post 62. Latch keys 60 are inserted into corresponding latch key receptacles (not shown) of the pod door 74 as pod 70 is advanced towards the port door 30 by advance plate assembly 50. Latch keys 60 are rotated on the axis of post 62, interacting with a mechanism (not shown) internal to pod door 74, causing latches to disengage from lip 76 of pod 70. An example of a door latch assembly within a pod door adapted to receive and operate with latch keys is disclosed in U.S. Pat. No. 4,995,430, entitled “Sealable Transportable Container Having Improved Latch Mechanism,” which is incorporated herein by reference. Another example is presented in U.S. Pat. No. 6,502,869, issued on Jan. 7, 2003 to Rosenquist et al., also incorporated herein by reference.

In addition to disengaging pod door 74 from the pod 70, rotation of the latch keys 60 locks the keys in their respective latch key receptacles, thereby coupling the pod door 74 to the port door 30. A conventional load port includes two latch keys 60, each of which pairs are structurally and operationally identical to each other. Once the latches are disengaged, port door 30 may be retracted thereby removing pod door 74 from pod 70.

Alignment pins 34 ensure a degree of alignment between port door 30 and pod door 74, so that pod door 74 will be sufficiently aligned with aperture 22 to pass through aperture and be stowed in the interior of process tool 40. However, these alignment pins may not always be sufficiently precise to ensure alignment between pod door 74 and lip 76 of pod 70 when replacing pod door 74, particularly if any amount of shifting has occurred between pod door 74 and port door 30. Accordingly, it is common practice to provide a vacuum system (not shown) for retaining pod door 74 against port door 30 and prevent any relative movement between the two. The U.S. Pat. No. 6,502,869 mentioned above describes an alternative mechanism to prevent relative movement between the port door and the pod door. In that system, the latch keys are biased in a rearward direction after engaging the pod door, thereby compressing the pod door between the back of the latch keys and the pod door, the friction between pod door 74 and port door 30 preventing any relative movement.

### SUMMARY

Broadly speaking, the present invention addresses a desire to make load ports easily reconfigurable to accommodate pods of varying capacities and sizes these needs by providing a bridge loadport as described hereinbelow. It should be appreciated that the present invention can be implemented in numerous ways, including as a process, an apparatus, a system, a device, or a method. Several inventive embodiments of the present invention are described below.

In one embodiment, a bridge loadport is provided. The bridge load port includes a tool interface, an advance plate assembly, a port plate, and a port door. The tool interface extends vertically and is configured to substantially cover one end of a process tool. The advance plate assembly is supported on the front side of the tool interface and is configured to support a front-opening unified pod (pod). The port plate extends vertically, covering an upper portion of the tool interface. An aperture having a size and shape that substantially matches a size and shape of a door of a pod is formed in the port plate. The port door has a port door actuator and a port door face attached to the port door actuator. The port door face is movable with respect to the port door actuator along an axis that is perpendicular to the aperture. The port door actuator includes a latch key extending from a front of the port door actuator through the port door face and from a front of the port door face.

In another embodiment, a method for loading a pod to a load port of a process tool is provided. The method includes mounting the pod onto an advance plate of an advance plate assembly, the advance plate being in a retracted position. The advance plate is advanced from the retracted position to an advanced position. In the advanced position, the pod forms a proximity seal with a port plate of the load port. A latch key is extended from a port door into a latch key receptacle of a door of the pod, which is latched to a lip of the pod. The extending causes a port door face to engage the door of the pod, the port door face being biased by a spring against the door of the pod. The latch key is rotated, causing the door of the pod to disengage from the lip of the pod. The port door is then moved to an open position, the moving causing the door of the pod to be removed from a front opening of the pod and allowing substantially unobstructed access to an interior of the pod.

In yet another embodiment, a load port is provided that includes a port plate, and a port door. The port plate includes an aperture having a size and shape that substantially matches a size and shape of a door of a pod, the pod having a selected maximum capacity and being capable of holding substrates of a selected diameter. The port door has a port door actuator and a port door face attached to the port door actuator. The port door may be positioned in a closed position in which the port door face substantially occludes the aperture in the port plate and an open position in which the aperture is substantially unobstructed by the port door. The port door actuator includes a latch key extending from a front of the port door actuator through the port door face and from a front of the port door face. The latch key extends from the front side of the tool interface when the port door is in the closed position.

In yet another embodiment, a method for operating a load port of a process tool is provided. The method includes selecting a pod size of a pod for transporting substrates to and from a process tool. The pod size has a capacity defined as a maximum number of substrates that the pod can contain at one time, and a substrate dimension, the substrate dimension being a size of each of the substrates that the pod can contain. A port plate is selected from among a plurality of port plates. Each of the plurality of port plates has an aperture corresponding to a differing pod size. The selected port plate has an aperture corresponding to a size of the front opening of the pod of the selected pod size. The selected port plate is attached to a tool interface of a load port. A port door face is selected from among a plurality of port door faces of differing sizes. The selected port door face has a shape corresponding to a front surface of a door of the pod of the selected pod size. The selected port door face is attached to the port door actuator.

The advantages of the present invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, and like reference numerals designate like structural elements.

FIGS. 1 and 2 are isometric and profile views showing a conventional load port configured to interface with a standard 300 mm, 25-wafer pod.

FIG. 3 shows an isometric view of an exemplary bridge loadport.

FIGS. 4A and 4B show embodiments of a load port for the bridge loadport of FIG. 3.

FIGS. 5, 6, 7, and 8 show schematic representations of the loadport of FIG. 4B in various stages of operation.

FIG. 9 shows a schematic representation of a control system for the bridge loadport of FIG. 3.

FIGS. 10A, 10B, 10C, and 10D show the bridge loadport of FIG. 3 in various configurations.

### DETAILED DESCRIPTION

In the following description, numerous specific details are set forth in order to provide a thorough understanding of the present invention. However, it will be apparent to one skilled in the art that the present invention may be practiced without some of these specific details. In other instances, well known process operations and implementation details have not been described in detail in order to avoid unnecessarily obscuring the invention.

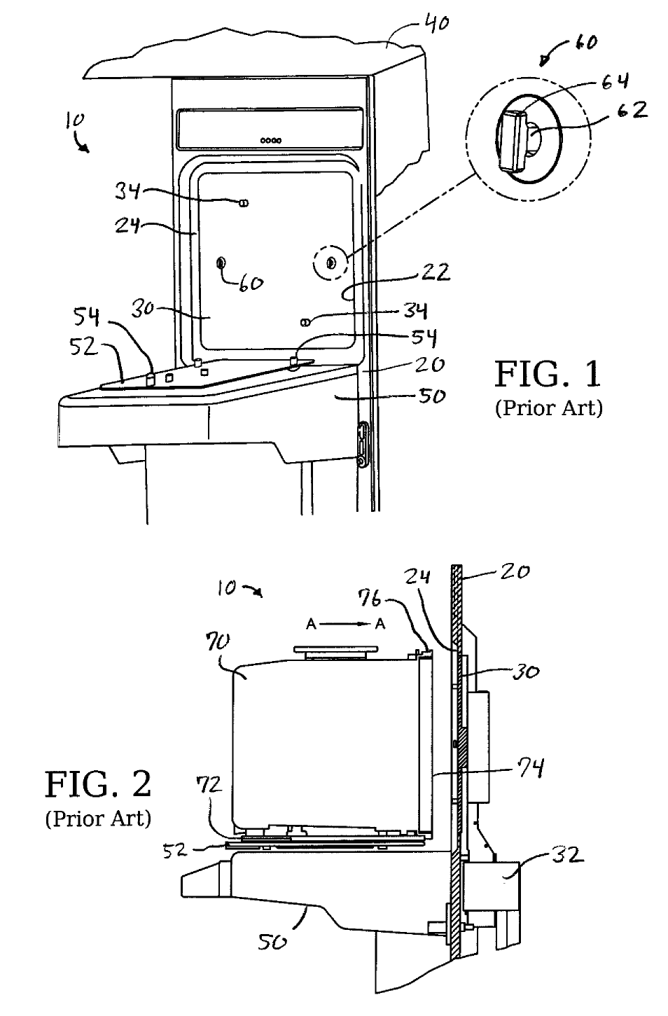

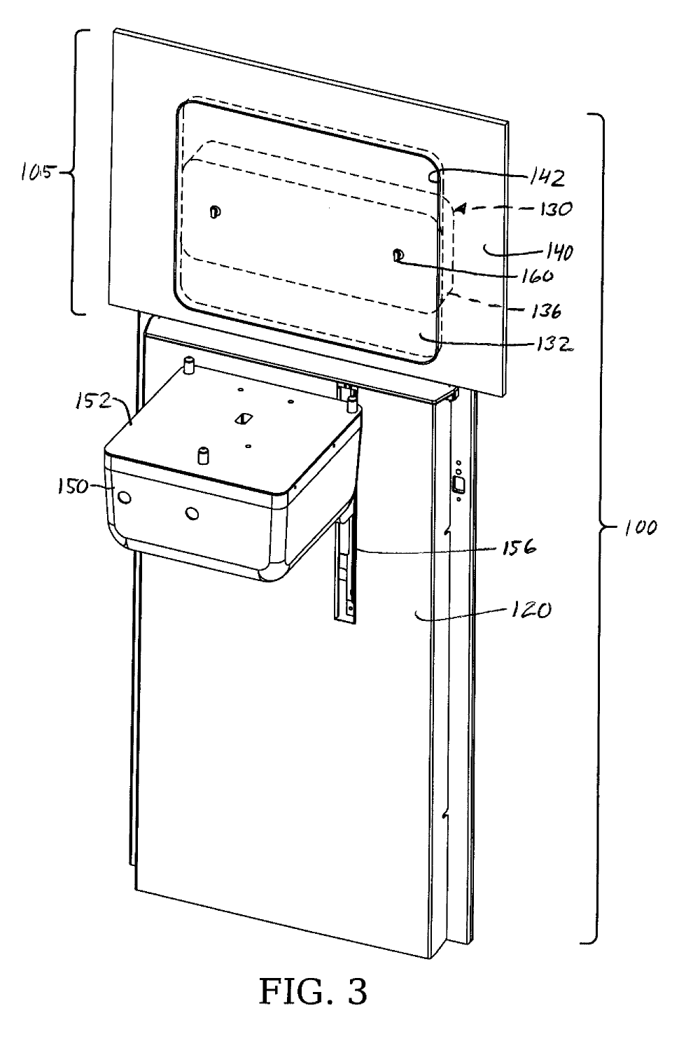

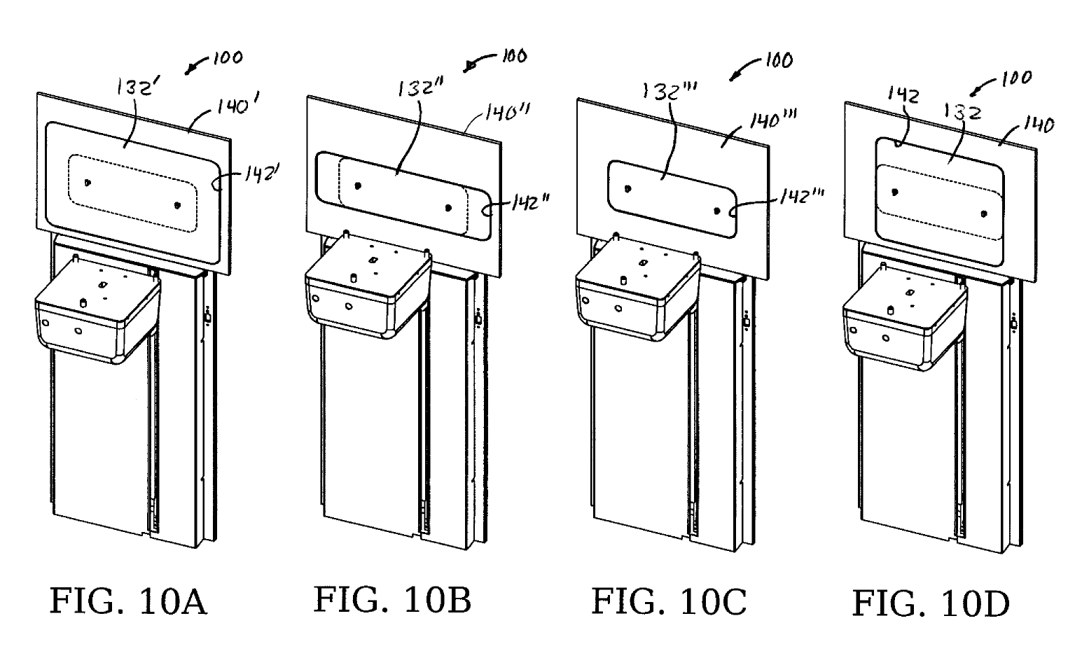

FIG. 3 shows an exemplary bridge loadport 100 having a tool interface 120 having a generally vertically extending plate. In one embodiment, tool interface 120 conforms to an industry standard BOLTS interface, and is configured to substantially cover one end of a process tool, such as process tool 40 shown in FIG. 1. Bridge loadport 100 also includes an advance plate assembly 150 having an advance plate 152 for mounting a pod as described in further detail below. Advance plate assembly 150 includes an elevator mechanism 156 configured to raise and lower advance plate 152 for purposes that will be made clear below with reference to FIGS. 10A-10D. In one embodiment, elevator mechanism 156 is implemented using a linear actuator, such as a belt drive, lead screw, or other servo actuator as would occur to those skilled in the art. In addition, advance plate assembly 150 includes an internal actuator for moving the advance plate 152 from a retracted position, which is spaced from tool interface 120 to an advanced position, proximate tool interface 120.

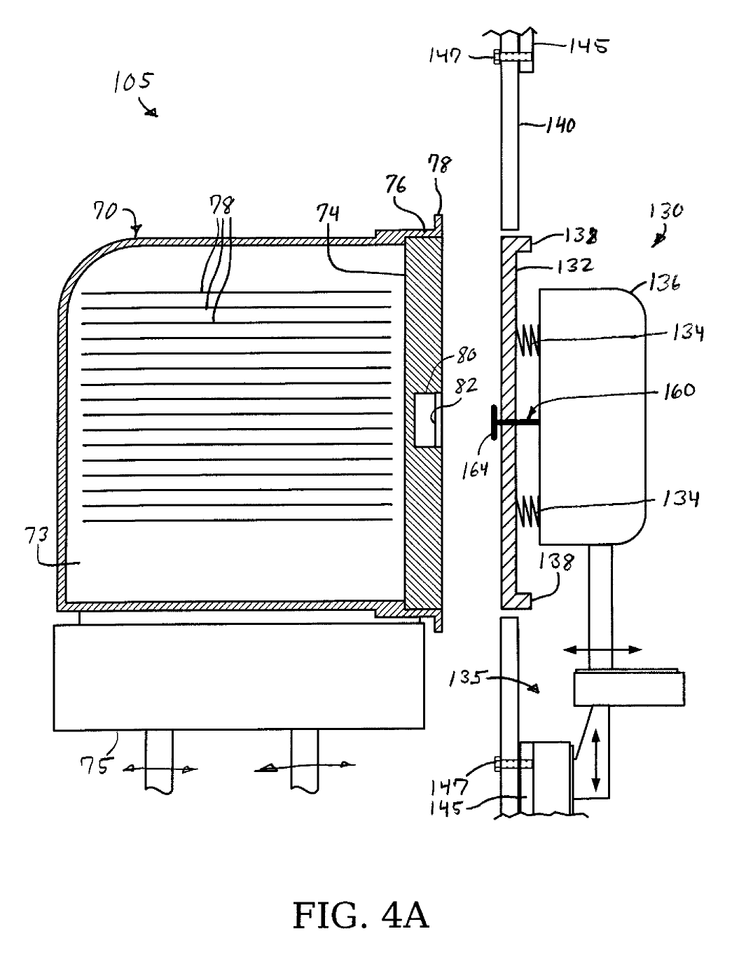

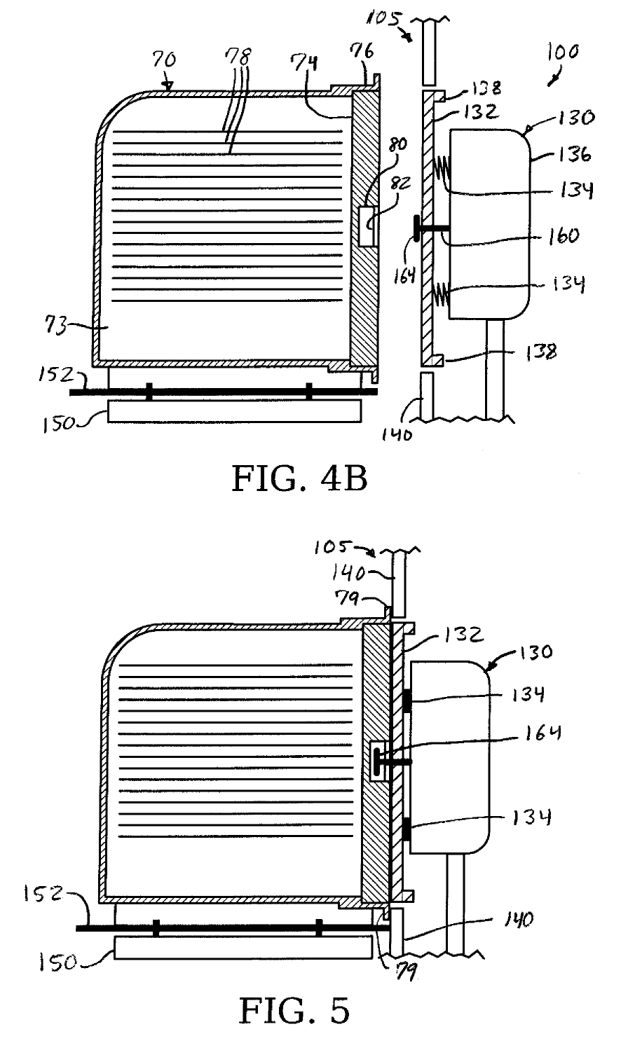

Bridge loadport 100 also includes a load port 105 having a port plate 140. Port plate 140 defines an aperture 142 that is shown substantially occluded by port door face 132 of port door 130. In one embodiment, port plate 140 is attached to a frame (not visible in FIG. 3) of bridge loadport 100 using a releasable attaching means such as a plurality of screws or one or more latches. A partial cross section view of loadport 105 is shown in FIG. 4A. It can be seen here that port plate 140 is attached to frame 145 by screws 147. In addition, port door face 132 is retained to port door actuator 136 by a coupling. In one embodiment, the coupling simply fixes port door face 132 to port door actuator 136 in the absence of springs 134. For example, the coupling could include a plurality of screws, latches, clips, etc. In another embodiment, the coupling allows for relative movement between port door face 132 and port door actuator 136. In this embodiment, the coupling could include one or more alignment means which permit relative movement only in the direction perpendicular to the plane of the port door face.

Such alignment means may be formed by the axial shafts of the two latch keys 160, in combination with corresponding surfaces in the port door, or additional alignment means (not shown) may be provided such as a linear bearing, alignment pins, etc., to ensure port door face smoothly moves with one degree of freedom along a single axis perpendicular to port door actuator 130, substantially preventing rotational movement or translational movements along other axes. The additional alignment means can also include a catch for retaining port door face 132 to port door 136. In either embodiment, the coupling may be cooperative with any of a plurality of port door faces of differing sizes and shapes, depending on the size of pod 70.

Although represented as helical springs, springs 134 may be implemented in any suitable fashion, and may, for example, be formed integrally with port door face 132 or port door actuator 136. Port door face, e.g., may be made from a suitable plastic material, wherein at least the front surface is formed from a material sufficiently stiff to meet flatness standards promulgated for process tool interface port doors by Semiconductor Equipment and Materials International (SEMI). In one embodiment, port door face 132 includes an extended rim 138, shaped to improve the air flow and resulting proximity seal between port door face 132 and aperture 142 of port plate 140.

Pod 70 includes an interior space 73 enclosed by a pod door 74. Pod door 74 includes, for each latch key 160, a latch key receptacle 80 (only one being visible in FIG. 4A) having an internal shoulder 82. In FIG. 4A, pod 70 is mounted to a support 75 capable of moving left and right to advance pod 70 to port plate 140 for loading and to retract pod 70 from port plate 140 for unloading. FIG. 4B shows a second embodiment wherein pod 70 is mounted to an advance plate 152, which is moved left and right by advance plate assembly 150, which is shown in more detail in FIG. 3.

FIGS. 5-8 show various stages of operation of load port 105. It should be noted that these operations apply both to the embodiments of FIG. 4A and FIG. 4B. In FIG. 5, the pod support, in this case advance plate 152, is moved to the advanced position, thereby bringing front flange 79 of pod 70 to port plate 140. In one embodiment, front flange 70 is brought sufficiently close to port plate 140 to form a proximity seal therewith.

In one embodiment, port door actuator 136 moves forward after pod 70 is moved to the advanced position, the forward movement of port door actuator 136 causing springs 134 to compress and latch keys 160 to be extended into latch key receptacles 80. In another embodiment, port door actuator 36 is moved into the forward position prior to or during the advance of pod 70. In either case, latch keys 160 are inserted into latch key receptacles 80 and springs 134 are in a compressed state, biasing port door face 132 into engagement with pod door 74. The movement of port door actuator is effectuated by mechanism 135 shown by way of example in FIG. 4A. Mechanism 135 is capable of moving port door 130 on a Y and a Z axis, the Y-axis being left and right as viewed in FIG. 5, and the Z-axis being up and down.

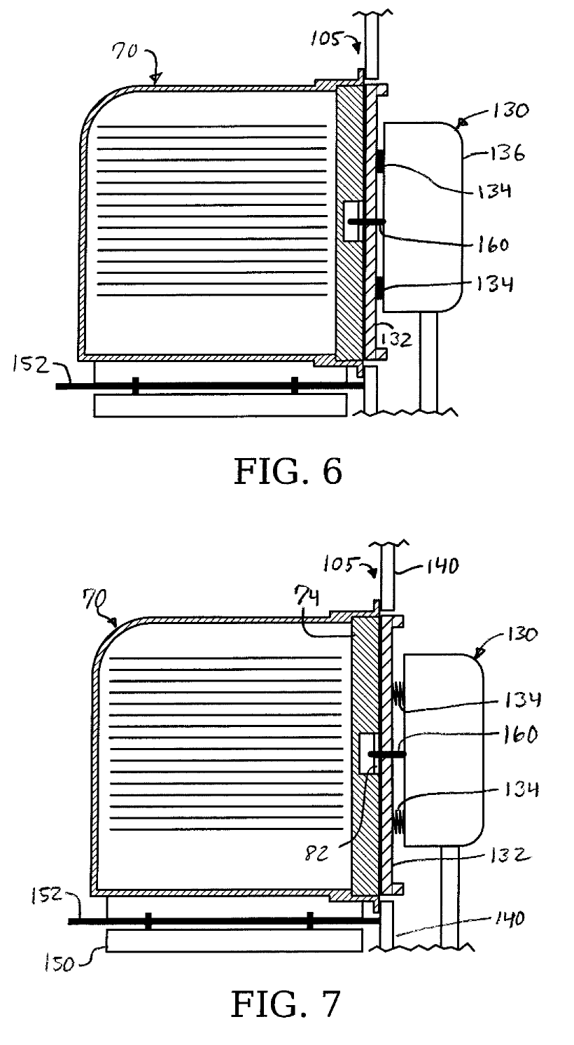

In FIG. 6, latch key 160 is rotated 90° to unlatch the pod door from the pod. Port door actuator 136 includes an actuator mechanism (not shown) such as a servo or solenoid causing latch key 160 to rotate. Rotation of latch key 160 interacts with an internal mechanism (not shown) in pod door 74. The internal mechanism causes pod door latches to retract from slots (not shown) formed in lip 76 of pod 70, thereby releasing pod door 74 from pod 70. Such a mechanism is described in more detail in U.S. Pat. Nos. 4,995,430 and 6,502,869, previously incorporated herein by reference. In addition, the rotation of latch keys 160 cause the pod door 74 to be coupled to port door 30, due to interference between cross bar 164 (see FIG. 4A) and internal shoulder 82 of pod door 74.

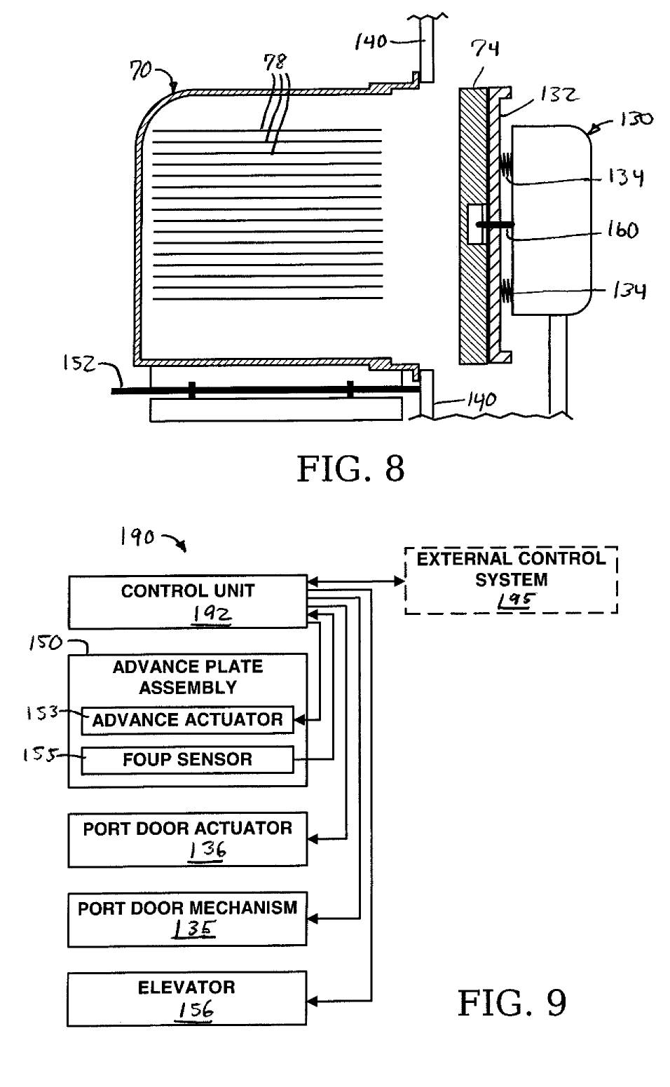

In FIG. 7, port door 130 is shown moved a small distance away from aperture 142, allowing springs 13 to decompress slightly. In the position shown in FIG. 7, the back edges of cross bar 164 (FIGS. 4A, 4B, 5) of latch key 160 just engage internal shoulders 82 of latch key receptacles 80 formed in pod door 74. Note that springs 134 remain in a compressed state, exerting a force against port door face 132, which in turn is pressed against pod door 74. Resulting friction between port door face 132 and pod door 74 ensures that there is no relative movement between pod door 74 and port door face 132. Port door actuator 136 continues to move in a rearward direction from the position shown in FIG. 7, as shown in FIG. 8, wherein pod door 74 is removed entirely away from pod 70. From this position, port door 30, along with pod door 74, may move down using an actuator such as actuator 132 shown in FIG. 4A. Once port door 30 is moved down, access to substrates 78 in pod 70 becomes substantially unobstructed either by pod door 74 or port door 30.

Replacement of pod door 74 can be achieved by performing, in reverse, the steps described above with reference to FIGS. 4B through 8. Specifically, port door actuator 130 is moved forward from the position shown in FIG. 8 until pod door 74 is positioned within pod lip 76, as shown in FIG. 7. Then, port door actuator 130 continues its forward movement until cross bar 164 of latch key 160 disengages from internal shoulder 82 in latch key receptacle 80, as shown in FIG. 6. Then, the latch key is rotated 90° to a vertical position shown in FIG. 5, causing the pod door 74 to engage lip 76 of pod 70. Then, advance plate 152 retracts to the retracted position shown in FIG. 4B, and optionally, port door actuator 136 moves to a retracted position.

FIG. 9 shows an exemplary control system 190 for controlling the operations of bridge loadport 100, described above with reference to FIGS. 3-8. Control system 190 includes a control unit 192 which is in communication with an external control system 195. In one embodiment, external control system 195 may provide load and unload directives to control unit 192, in response to which control unit 192 operates bridge loadport 100 to load and unload a pod. Advance plate assembly 150 (or other support system such as support 75 shown in FIG. 4A) includes an advance actuator 153 for moving the pod 70 between the retracted and advanced positions described previously. Advance plate assembly 150 may include a pod sensor 155 that detects a presence of a pod on the advance plate. For example, pod sensor 155 may be implemented using a microswitch or a proximity sensor to detect when a pod is properly mounted on advance plate 152. Pod sensor 155 may further be adapted to sense the particular type or configuration of pod which has been placed on the loadport, or the loadport control unit 192 may receive a signal from the external control system 195 conveying such information.

Upon receiving a “load” directive from external control system 195, control unit 192 detects whether a pod is mounted by way of pod sensor 155, then causes advance plate 152 to move to the advanced position (shown, e.g., in FIG. 5) by activating advance actuator 153. Control unit 192 also actuates port door mechanism 132 (shown in FIG. 4A) to cause the port door actuator 136 to move forward so that the latch keys 160 extend into latch key receptacles 80 as shown in FIG. 5. Control unit 192 then causes port door actuator 136 to rotate the latch keys 160 to disengage pod door 74 from outer lip 76 of pod 70. Control unit 192 then actuates port door mechanism 32 to cause port door 30 to move from the closed position to the open position described above. These operations are performed substantially in reverse upon receipt by control unit 190 of an “unload” directive from external control system 195. In one embodiment, control unit 192 also operates elevator 156 shown in FIG. 3, to raise and lower advance plate assembly 150, for reasons that will be made clear in the discussion below referencing FIGS. 10A-10D.

Bridge loadport 100 described above may be easily reconfigured for different size pods by replacing port plate 140 and port door face 132. FIGS. 10A-10D show exemplary configurations. In FIG. 10A, bridge loadport 100 includes a port plate 140′ having an aperture 142′ sufficiently tall and wide to accommodate a large capacity pod designed to contain a maximum of 25 450 mm wafers. In FIG. 10B, bridge loadport 100 includes a port plate 140″ having an aperture 142″ sufficiently tall and wide to accommodate a low capacity pod designed to contain a maximum of 10 wafers 450 mm wafers. Since a pod of this capacity has a lower profile, advance plate assembly 150 is lifted from the position shown in FIG. 10A to ensure alignment between the pod door and port door face 132 and between latch keys 160 and the latch key receptacles formed on the pod.

Advance plate assembly 150 may be lifted by elevator 156 shown by way of example in FIG. 3. In one embodiment, elevator 156 is manually operated, e.g., by using a manually operated vertically adjustable support or by manually removing advance plate assembly 150 from a first location on and reattaching advance plate assembly 150 to load port 100 at a different elevation. In another embodiment, elevator 156 is automatically adjusted in response to signals from control unit 192 (FIG. 9).

In FIG. 10C, bridge loadport 100 includes a port plate 140′″ having an aperture 142′″ sized to correspond with a low capacity pod designed to contain a maximum of 10 wafers each 300 mm in diameter. Since these wafers have a smaller diameter, the pod used to transport them is not as wide, and therefore aperture 142′″ is not as wide as the apertures 142′ and 142″ shown in FIGS. 10A and 10B, respectively. FIG. 10D shows a bridge loadport 100 configured to cooperate with a standard 25 300 mm wafer, pod, substantially as shown in FIG. 3, but presented again here for comparison with configurations in FIGS. 10A-10C.

While FIGS. 10A through 10D show by way of example, pods and loadports configured for receiving and storing semiconductor wafers, other substrate types, such as magnetic media, LCD panels, etc., can be received and stored using loadports and pods as described above. It should also be recognized that various mechanisms, aside from the spring-biased door face described above with reference to FIGS. 4-8, may be used to retain a pod door to the port door. For example, suction means, or the twist and pull latch key mechanism described in the above-mentioned U.S. Pat. No. 6,502,869. The interchangeable port plates and port door faces allows easy reconfiguration of a load port that is initially configured to receive pods of a first size to be subsequently configured to receive pods of a second size, wherein the first and second pod sizes can differ with respect to a lot size difference, a substrate dimension difference, or both.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A bridge loadport comprising:
a tool interface extending substantially in a vertical direction and configured to substantially cover a portion of one side of a process tool, the tool interface having a front side and a back side;
an advance plate assembly supported on the front side of the tool interface, the advance plate being configured to support a pod;
a port plate, the port plate extending vertically and covering at least an upper portion of the tool interface, the port plate including an aperture having a size and shape that substantially matches a size and shape of a door of a pod, the pod being having a selected maximum capacity and being capable of holding substrates of a selected size; and
a port door having a port door actuator and a port door face attached to the port door actuator, the port door having a closed position in which the port door face substantially occludes the aperture in the port plate and an open position in which the aperture is substantially unobstructed by the port door, the port door face being movable with respect to port door actuator along an axis perpendicular to the aperture, the port door actuator including a latch key extending from a front of the port door actuator through the port door face and from a front of the port door face, the latch key thereby extending from the front side of the tool interface when the port door is in the closed position.

2. The bridge loadport of claim 1, further comprising a second port plate having an differently-sized aperture, the differently-sized aperture having a size and shape to substantially match a size and shape of a different pod, the different pod having a second selected maximum capacity and being capable of holding substrates of a second selected size, wherein at least one of the second selected capacity or the second selected size is different from the selected capacity and the selected size, respectively, of the pod, the bridge loadport being configurable for the different pod, by replacing the port plate with the second port plate.

3. The bridge loadport of claim 2, wherein the bridge loadport is configurable for the different pod by also replacing the port door face with a second port door face, the second port door face having a size and a shape to substantially occlude the differently-sized aperture of the second port plate.

4. The bridge loadport of claim 3, further comprising an elevator for raising and lowering the advance plate assembly, to ensure alignment between the pod and the different pod with the port door face and the second port door face, respectively.

5. The bridge loadport of claim 4, wherein said alignment is defined as attaining the position in which the latch keys and latch key receptacles are in the correct orientation for engagement.

6. The bridge loadport of claim 1, wherein the port door face is biased away from the port door actuator by a spring, the port door face being retained to the port door actuator by one of a catch or the latch key.

7. The bridge loadport of claim 6, wherein the spring operates to bias the port door face against the pod door when the pod door is engaged by the latch keys, the biasing creating friction between the pod door and the port door face sufficient to prevent relative movement between the pod door and the port door face while the port door is being opened or closed.

8. The bridge loadport of claim 1, further comprising:
a control unit, the control unit being in electronic communication with the advance plate assembly, the port door actuator, and the port door mechanism; the control unit causing the advance plate to move to an advanced position proximate the tool interface; move the port door actuator out causing the latch keys to extend into corresponding latch key receptacles of the pod, and rotate the latch keys so that each of the latch keys engage an internal shoulder formed in each of the latch key receptacles.

9. The bridge loadport of claim 8, further comprising an elevator for raising and lowering the advance plate assembly, the elevator aligning between the pod and the different pod with the port door face and the second port door face, respectively, the elevator being responsive to signals from the control unit.

10. A method for loading a pod to a load port of a process tool, the method comprising:
mounting the pod onto an advance plate of an advance plate assembly, the advance plate being in a retracted position;
advancing the advance plate from the retracted position to an advanced position, the pod forming a proximity seal with a port plate of the load port when the advance plate is moved to the advanced position;
extending a latch key from a port door into a latch key receptacle of a door of the pod, the door of the pod being latched to a lip of the pod, the extending causing a port door face to engage the door of the pod, the port door face being biased by a spring against the door of the pod;
rotating the latch key, the rotating causing the door of the pod to disengage from the lip of the pod; and
moving the port door to an open position, the moving causing the door of the pod to be removed from a front opening of the pod and allows substantially unobstructed access to an interior of the pod.

11. The method of claim 10, wherein the method further comprises:
selecting a port plate having an aperture substantially matching a size of the front opening of the pod;
attaching the selected port plate to the bridge loadport;
selecting the load port door face having a shape substantially matching a front surface of the door of the pod; and
attaching the selected load port door face to the port door actuator.

12. The method of claim 11, further comprising adjusting an elevation of the advance plate assembly so that the latch key receptacle of the door of the pod is aligned with the latch key of the port door when the pod is mounted on the advance plate.

13. The method of claim 107 further comprising receiving a “load” directive at the control unit, the advancing, extending, rotating, and moving occurring automatically in response to signals generated by a control unit in response to the receiving of the “load” directive.

14. The method of claim 10, wherein, simultaneously with the extending of the latch key into the latch key receptacle, the spring is compressed, the compression creating friction between the pod door and the port door face sufficient to prevent relative movement between the pod door and the port door face during the moving.

15. A loadport comprising:
a port plate, the port plate including an aperture having a size and shape that substantially matches a size and shape of a door of a pod, the pod having a selected maximum capacity and being capable of holding substrates of a selected size; and
a port door having a port door actuator and a port door face attached to the port door actuator, the port door having a closed position in which the port door face substantially occludes the aperture in the port plate and an open position in which the aperture is substantially unobstructed by the port door, the port door face being movable with respect to the port door actuator along an axis perpendicular to the aperture, the port door actuator including a latch key extending from a front of the port door actuator through the port door face and from a front of the port door face, the latch key thereby extending from the front side of the tool interface when the port door is in the closed position.

16. The bridge loadport of claim 15, further comprising a second port plate having an differently-sized aperture, the differently-sized aperture having a size and shape to substantially match a size and shape of a different pod, the different pod having a second selected maximum capacity and being capable of holding substrates of a second selected size, wherein at least one of the second selected capacity or the second selected size is different from the selected capacity and the selected size, respectively, of the pod, the bridge loadport being configurable for the different pod, by replacing the port plate with the second port plate.

17. The loadport of claim 16, wherein the bridge loadport is configurable for the different pod by also replacing the port door face with a second port door face, the second port door face having a size and a shape to substantially occlude the differently-sized aperture of the second port plate.

18. The loadport of claim 17, further comprising an elevator for raising and lowering the pod to ensure alignment between the pod and the different pod with the port door face and the second port door face, respectively.

19. The loadport of claim 15, wherein the port door face is biased away from the port door actuator by a spring, the port door face being retained to the port door actuator by one of a catch or the latch key.

20. The loadport of claim 19, wherein the spring operates to bias the port door face against the pod door when the pod door is engaged by the latch keys, the biasing creating friction between the pod door and the port door face sufficient to prevent relative movement between the pod door and the port door face while the port door is being opened or closed.

21. The loadport of claim 15, further comprising;
a control unit, the control unit being in electronic communication with the port door actuator and the port door mechanism, the control unit causing the port door mechanism to move the port door actuator forward, thereby causing the latch keys to extend into corresponding latch key receptacles of the pod, the control unit further causing the port door actuator to rotate the latch keys so that each of the latch keys engage an internal shoulder formed in each of the latch key receptacles.

22. The loadport of claim 21, further comprising an elevator for raising and lowering the pod, the control unit aligning the pod and the different pod with the port door face and the second port door face, respectively, by activating the elevator.

23. A method for operating a load port of a process tool, the method comprising:
selecting a pod size of a pod for transporting substrates to and from a process tool, the pod size having a capacity defined as a maximum number of substrates that the pod can contain at one time, and a substrate dimension, the substrate dimension being a size of each of the substrates that the pod can contain;
selecting a port plate from among a plurality of port plates, each of the plurality of port plates having an aperture corresponding to differing pod size, the selected port plate having an aperture corresponding to a size of the front opening of the pod of the selected pod size;
attaching the selected port plate to a tool interface of a load port;
selecting a port door face from among a plurality of port door faces of differing sizes, the selected port door face having a shape corresponding to a front surface of a door of the pod of the selected pod size; and
attaching the selected port door face to the port door actuator.

24. The method of claim 23, wherein the selected port door face is sized to substantially occlude the aperture of the selected port plate and has a perimeter that does not extend beyond a perimeter of the aperture of the selected port plate.

25. The method of claim 23, wherein the port door face fits at least partially within the aperture of the selected port plate.

26. The method of claim 23, wherein the port door actuator comprises a coupling, the coupling being universal for any of the port door faces of the plurality of port door faces.

27. The method of claim 23, further comprising:
removing an existing port plate and existing port door face from the tool interface prior to attaching the selected port plate to the tool interface and the selected port door face to the door actuator, the existing port plate having an aperture size corresponding to a previous pod size, wherein the previous pod size differs from the selected pod size with respect to at least one of a lot size difference or a substrate dimension difference.

28. The method of claim 23, further comprising adjusting an elevation of an advance plate assembly, the advance plate assembly supporting the pod when interfacing with the tool interface, the elevation being adjusted so that a latch key receptacle of a door of the pod is aligned with a latch key of the port door when the pod is mounted on the advance plate.

29. The method of claim 23, further comprising:
mounting the pod onto an advance plate of an advance plate assembly, the advance plate being in a retracted position;
advancing the advance plate from the retracted position to an advanced position, the pod forming a proximity seal with the port plate when the advance plate is moved to the advanced position;
extending a latch key from a port door into a latch key receptacle of a door of the pod, the door of the pod being latched to a lip of the pod, the extending causing a port door face to engage the door of the pod;
rotating the latch key, the rotating causing the door of the pod to disengage from the lip of the pod; and
moving the port door to an open position, the moving causing the door of the pod to be removed from a front opening of the pod and allows substantially unobstructed access to an interior of the pod.

30. The method of claim 29, wherein the port door face is biased by a spring against the door of the pod.

31. The method of claim 30, wherein, simultaneously with the extending of the latch key into the latch key receptacle, the spring is compressed, the compression creating friction between the pod door and the port door face sufficient to prevent relative movement between the pod door and the port door face during the moving.

32. The method of claim 29, further comprising receiving a “load” directive at the control unit, the advancing, extending, rotating, and moving occurring automatically in response to signals generated by a control unit in response to the receiving of the “load” directive.
